(19) United States
(12) Patent Application Publication
(10) Pub. No.: US 2014/0291783 A1
(43) Pub. Date: Oct. 2, 2014

(54) COVER FOR A MEMS MICROPHONE

(71) Applicant: Knowles Electronics, LLC, Itasca, IL (US)

(72) Inventors: Dennis Talag, Woodridge, IL (US); Kurt Friel, Sycamore, IL (US); Tony Lim, Naperville, IL (US)

(73) Assignee: Knowles Electronics, LLC, Itasca, IL (US)

(21) Appl. No.: 14/220,614

(22) Filed: Mar. 20, 2014

Related U.S. Application Data
(60) Provisional application No. 61/804,087, filed on Mar. 21, 2013.
(60) Provisional application No. 61/804,004, filed on Mar. 21, 2013.

(51) Int. Cl. H04R 1/04; B81B 7/00

(52) U.S. Cl. CPC H04R 1/04; B81B 7/0077
USPC 257/416

(57) ABSTRACT

A microphone assembly includes a base, a cover, and a microelectromechanical system (MEMS) die. The cover extends at least partially over and is coupled to the base. The cover and the base form a cavity. The MEMS die is coupled to the base and disposed within the cavity. At least a portion of the cover is constructed of a copper-nickel-zinc alloy that is effective in preventing solder from moving from a first portion of the cover to a second portion of the cover.

### CROSS REFERENCE TO RELATED APPLICATIONS

This patent claims benefit under 35 U.S.C. §119 (e) to U.S. Provisional Application No. 61/804,087 entitled “Cover for a MEMS Microphone” filed Mar. 21, 2013, and Application No. 61/804,004 entitled “Cover for a MEMS Microphone” filed Mar. 21, 2013, the contents of which are incorporated herein by reference in their entirety.

### TECHNICAL FIELD

This application relates to MicroElectroMechanical components and, more specifically, the covers of these devices.

### BACKGROUND OF THE INVENTION

MicroElectroMechanical System (MEMS) devices include microphones and speakers to mention two examples. In the case of a MEMS microphone, sound energy enters through a sound port and vibrates a diaphragm and this action creates a corresponding change in electrical potential (voltage) between the diaphragm and a back plate disposed near the diaphragm. This voltage represents the sound energy that has been received. Typically, the voltage is then transmitted to an electric circuit (e.g., an integrated circuit such as an application specific integrated circuit (ASIC)). Further processing of the signal may be performed on the electrical circuit. For instance, amplification or filtering functions may be performed on the voltage signal at the integrated circuit.

The internal devices (e.g., integrated circuit, MEMS device) of a microphone are disposed within an assembly. For example, these devices may be attached to a base and covered with a cover. In other words, a cavity is formed by the cover and the internal devices (e.g., an integrated circuit, MEMS device) are disposed on the base within the cavity.

In many examples, the cover is coupled to the base of the acoustic device with solder. In fact, the cover may be attached to the base by solder on both on the inside portion (in the cavity and exposed to the MEMS device and the integrated circuit) and on the exterior of the device (exposed to the external environment).

In order that the solder can be attached to the cover (and thus make the connection to the base), the entire cover of previous systems is typically plated in gold (or some other appropriate metal) and then the attachment between the cover and base is made. However, in many situations after the attachment is made the device (including the solder) is re-heated. In these circumstances, the solder will melt and continues to interact with the plating, and “creeps” or flows up the cover. As this happens within the cavity, some solder can be discharged from the cover and cause failure to the MEMS device or integrated circuit within the cavity. On the outside of the cover, the “creeping” solder can continue to flow up the cover onto the surface of the cover and this will interfere with subsequent gasketing of the microphone.

### BRIEF DESCRIPTION OF THE DRAWINGS

For a more complete understanding of the disclosure, reference should be made to the following detailed description and accompanying drawings wherein:

FIG. 1 comprises a perspective view of a MEMS bottom port microphone according to various embodiments of the present invention;

FIG. 2 comprises a top view of the MEMS microphone of FIG. 1 according to various embodiments of the present invention;

FIG. 3 comprises a cross sectional view of the MEMS microphone taken along line A-A of FIG. 2 according to various embodiments of the present invention;

FIG. 4 comprises a cross sectional view of the MEMS microphone taken along line B-B of FIG. 2 according to various embodiments of the present invention;

FIG. 5 comprises a perspective view of a MEMS top port microphone according to various embodiments of the present invention;

FIG. 6 comprises a top view of the MEMS microphone of FIG. 5 according to various embodiments of the present invention;

FIG. 7 comprises a cross sectional view of the MEMS microphone taken along line G-G of FIG. 6 according to various embodiments of the present invention;

FIG. 8 comprises a cross sectional view of the MEMS microphone taken along line F-F of FIG. 6 according to various embodiments of the present invention; and

FIG. 9 comprises a cross sectional view of the MEMS microphone taken in area G of FIG. 6 according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

The present approaches provide a metal cover for a MicroElectroMechanical System (MEMS) microphone that eliminates or substantially reduces solder creep and provides other advantages described herein. In one aspect, a copper nickel zinc alloy that is approximately 55% copper, approximately 18% nickel, and approximately 27% zinc is used. In another aspect, this alloy has a material designation of C77000 under the Unified Numbering System (UNS). In one example, the alloy used may be the C77000 alloy produced by Wieland Metals, Inc.

In other aspects, the covers constructed of the copper nickel zinc alloys described herein are resistant to corrosion and have a good shelf life. Additionally, the covers constructed of the copper nickel zinc alloys provide for a good solderability and can be joined readily with soft solders. Further, the covers constructed of the copper nickel zinc alloys described herein do not need gold plating (or plating of any kind) or any surface finish. Being non-plated, these covers do not exhibit solder creeping on the cover surface during post assembly reflow processes. This eliminates customer returns due to visual defects. RF performance of the covers constructed of the copper nickel zinc alloys described herein is also adequate and comparable to previous approaches.

In still further aspects, since the covers constructed of the copper nickel zinc alloys described herein also include copper, the mechanical properties of the covers so-provided are similar to brass. The covers constructed of the copper nickel zinc alloys described herein can be constructed with existing tooling during the metal cover stamping process. Still further, the covers constructed of the copper nickel zinc alloys can be used as replacement on any microphone assembly with similar dimensions. In yet another advantage, the covers constructed as described herein can be used with existing production solder pastes and reflow techniques.

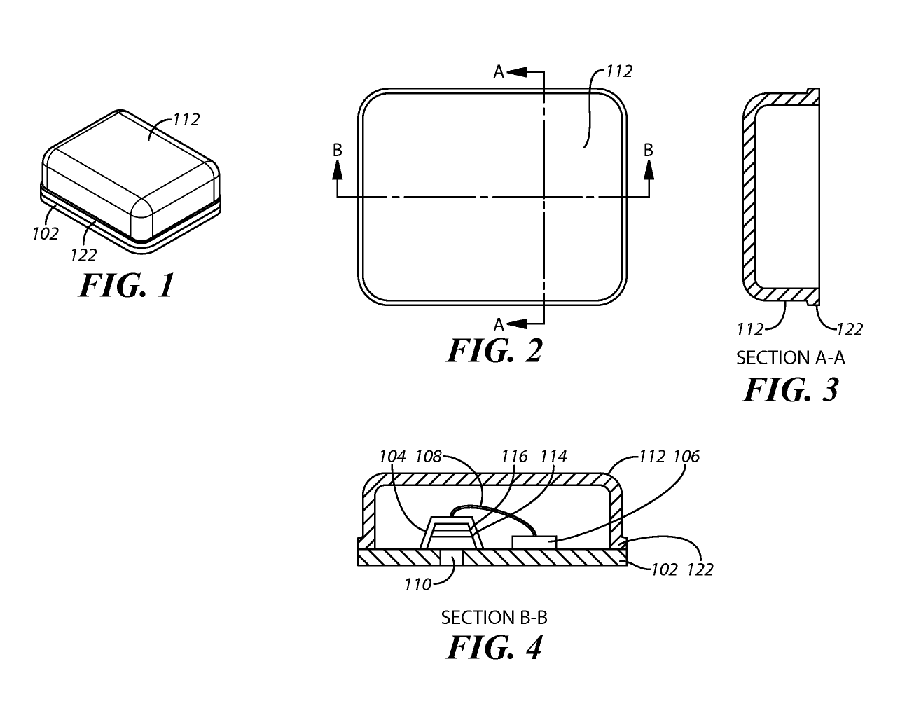

Referring now to FIGS. 1-4, one example of a microphone assembly 100 is described. The assembly 100 includes a base 102, a MicroElectroMechanical system (MEMS) device 104, an integrated circuit 106, wires 108, a port 110, and a cover 112. The port 110 extends through the base 102 making this a bottom port device. All dimensions shown in the drawings are in millimeters. However, it will be understood that other dimensions for the components and their placement may be used.

The base 102 is a substrate on which the cover and other components rest. In one example, the base 102 is constructed of an FR-4 material. Other examples of materials may also be used. The MEMS device 104 and the integrated circuit 106 are attached to the base 102 by, for example, an epoxy attachment.

The MEMS device 104 receives sound energy and converts the sound energy into electrical energy. In that respect, the MEMS device 104 may include a diaphragm 114 and a back plate 116. Sound energy enters the port 110 causes movement of the diaphragm 114 and this varies the electrical potential between the diaphragm 114 and the back plate 116. The current or voltage that is produced represents the sound energy that has been received by the MEMS apparatus 104.

The integrated circuit 106 is any kind of integrated circuit that performs any kind of processing function. In one example, the integrated circuit 106 is a buffer or an amplifier. Other examples of integrated circuits are possible. The wires 108 are connections that couple electrical components together. Internal conductive connections (not shown) are provided through the base 102 to allow the integrated circuit 106 to communicate with pads (not shown) on the base and thereby with external electrical devices.

Solder holds the cover and the base together. The solder, in one aspect, is on the inside and outside of the cover. Other examples of conductive fusion materials (e.g., conductive epoxy) are possible.

In one aspect, the entire cover 112 is constructed of a copper nickel zinc alloy that is approximately 55% copper, approximately 18% nickel, and approximately 27% zinc. In other cases, only a lip 122 of the cover is constructed of the alloy (and the remainder constructed of brass to mention one example). In another example, approximately one-half (the half nearest the base 102) of the cover 112 is constructed of the alloy. In these regards, it will be appreciated that the amount or section of the cover 112 actually constructed of the material may vary. In some aspects, the amount of copper can vary by +/−1.5% (from 53.5-56.5%); the amount of nickel can vary by +/−1% (from 17-19%). The amount of zinc can vary based upon the amount of variance of the other two materials. As will be readily appreciated, no plating or coating is used or needed for the cover 112.

The cover 112 can be stamped out from a piece of the alloy. Once formed, the cover 112 may be placed on the substrate and soldered into place using conventional soldering approaches.

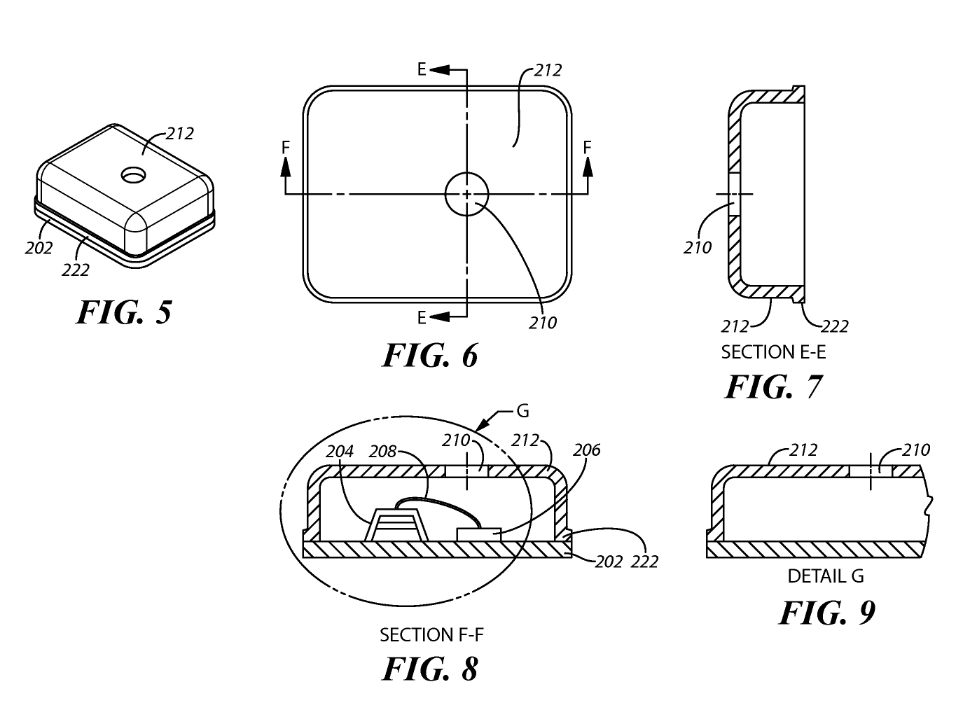

Referring now to FIGS. 5-9 one example of a microphone assembly 500 is described. The assembly 500 includes a base 502, a MicroElectroMechanical system (MEMS) device 504, an integrated circuit 506, wires 508, a port 510, and a cover 512. The port 510 extends through the cover 512 making this a top port device. All dimensions shown in the drawings are in millimeters. However, it will be understood that other dimensions for the components and their placement may be used.

The base 502 is a substrate on which the cover and other components rest. In one example, the base 502 is constructed of an FR-4 material. Other examples of materials may also be used. The MEMS device 504 and the integrated circuit 506 are attached to the base 502 by, for example, an epoxy attachment.

The MEMS device 504 receives sound energy and converts the sound energy into electrical energy. In that respect, the MEMS device 504 may include a diaphragm 514 and a back plate 516. Sound energy enters the port 510 causes movement of the diaphragm 514 and this varies the electrical potential between the diaphragm 514 and the back plate 516. The current or voltage that is produced represents the sound energy that has been received by the MEMS apparatus 504.

The integrated circuit 506 is any kind of integrated circuit that performs any kind of processing function. In one example, the integrated circuit 506 is a buffer or an amplifier. Other examples of integrated circuits are possible. The wires 508 are connections that couple electrical components together. Internal conductive connections (not shown) are provided through the base 502 to allow the integrated circuit 506 to communicate with pads (not shown) on the base and thereby with external electrical devices.

Solder holds the cover and the base together. The solder, in one aspect, is on the inside and outside of the cover. Other examples of conductive fusion materials (e.g., conductive epoxy) are possible.

In one aspect, the entire cover 512 is constructed of a copper nickel zinc alloy that is approximately 55% copper, approximately 18% nickel, and approximately 27% zinc. In other cases, only a lip 522 of the cover is constructed of the alloy (and the remainder constructed of brass to mention one example). In another example, approximately one-half (the half nearest the base 502) of the cover 512 is constructed of the alloy. In these regards, it will be appreciated that the amount or section of the cover 512 actually constructed of the material may vary. In some aspects, the amount of copper can vary by +/−1.5% (from 53.5-56.5%); the amount of nickel can vary by +/−1% (from 17-19%). The amount of zinc can vary based upon the amount of variance of the other two materials. As will be readily appreciated, no plating or coating is used or needed for the cover 512.

The cover 512 can be stamped out from a piece of the alloy. Once formed, the cover 512 may be placed on the substrate and soldered into place using conventional soldering approaches.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A microphone assembly, the assembly comprising:
a base;
a cover extending at least partially over and coupled to the base, the cover and the base forming a cavity;
a microelectromechanical system (MEMS) die coupled to the base and disposed within the cavity;
wherein at least a portion of the cover is constructed of a copper-nickel-zinc alloy that is effective in preventing solder from moving from a first portion of the cover to a second portion of the cover.

2. The assembly of claim 1, wherein the copper-nickel-zinc alloy covers the entire cover.

3. The assembly of claim 1, wherein the copper-nickel-zinc alloy covers approximately half of the cover nearest to the base.

4. The assembly of claim 3, wherein the remaining portion of the cover is constructed of brass.

5. The assembly of claim 1, wherein the cover comprises a lip in proximity to the base and the lip is constructed of the copper-nickel-zinc alloy.

6. The assembly of claim 1, wherein the copper-nickel-zinc alloy has a composition that is approximately 55 percent copper, approximately 18 percent nickel, and approximately 27 percent zinc.

7. The assembly of claim 1, wherein a port extends through the base.

8. The assembly of claim 1, wherein a port extends through the cover.
